(19) United States
(12) Patent Application Publication
(10) Pub. No.: US 2025/0050653 A1
(43) Pub. Date: Feb. 13, 2025

(54) AUXILIARY PRINTHEAD SUPPORT

(71) Applicant: Kateeva, Inc., Newark, CA (US)

(72) Inventor: Gregory Lewis, Mountain View, CA (US)

(73) Assignee: Kateeva, Inc., Newark, CA (US)

(21) Appl. No.: 18/721,816

(22) PCT Filed: Nov. 23, 2022
(86) PCT No.: PCT/US2022/080375

§ 371 Date: Jun. 19, 2024

Related U.S. Application Data
(60) Provisional application No. 63/265,866, filed on Dec. 22, 2021.

(51) Int. Cl. B41J 2/175; B41J 29/08

(52) U.S. Cl. CPC B41J 2/17596; B41J 29/08

(57) ABSTRACT

A inkjet printer is described herein that has a substrate staging portion with a discontinuous gas float system comprising a plurality of gas float members separated by gaps. The gaps enable interoperation with an end effector to deposit and retrieve substrates on a gas cushion provided by the gas float members.

### CROSS-REFERENCE TO RELATED APPLICATIONS

This application claims the benefit of U.S. Provisional Patent Application No. 63/265,866, filed on Dec. 22, 2021, which is hereby incorporated by reference.

### BACKGROUND

Industrial inkjet printers are used to apply materials to large substrates to form devices of all kinds. The substrates can be rigid or flexible, thick or thin, and can be made of an array of materials. The most common types of substrates used in this way are substrates made of various types of glass, which are processed to make electronic displays such as televisions and displays for smart phones.

Manufacturing using industrial inkjet printing has numerous advantages, among them flexibility, speed, and precision. As the demands for increasing precision and scale increase, there is a need for new printer designs capable of meeting those demands.

### SUMMARY

Embodiments described herein provide an inkjet printer, comprising a substrate support; a print assembly disposed across the substrate support; and a supply assembly spaced apart from the print assembly, connected to the print assembly, and disposed at a second elevation that is the same as the first elevation, or that is different from the first elevation by an amount selected to be compatible with pumping capacity of the supply assembly.

Other embodiments described herein provide an inkjet printer, comprising a substrate support having an input section and a print section; and a processing assembly comprising a support structure, a deposition section located in proximity to the print section of the substrate support, and a supply section spaced apart from the deposition section in a direction toward the input section of the substrate support, the processing assembly further comprising a processing head that extends from the deposition section to the supply section, the processing head having a printhead assembly located in the deposition section, a supply unit located in the supply section, and a conduit support connecting the printhead assembly with the supply assembly.

Other embodiments described herein provide an inkjet printer, comprising a substrate support; a print assembly disposed across the substrate support; a supply assembly spaced apart from the print assembly and configured with the print assembly to minimize a difference in elevation between the supply assembly and the print assembly; and a conduit support between the print assembly and the supply assembly.

### BRIEF DESCRIPTION OF THE FIGURES

FIG. 1A is a plan view of an inkjet printer according to one embodiment.

FIG. 1B is an elevation view of the inkjet printer of FIG. 1A.

FIG. 2A is a side view of a portion of a supply assembly according to one embodiment.

FIG. 2B is a plan view of a bearing plate according to one embodiment.

FIG. 3 is a plan view of an inkjet printer according to another embodiment.

### DETAILED DESCRIPTION

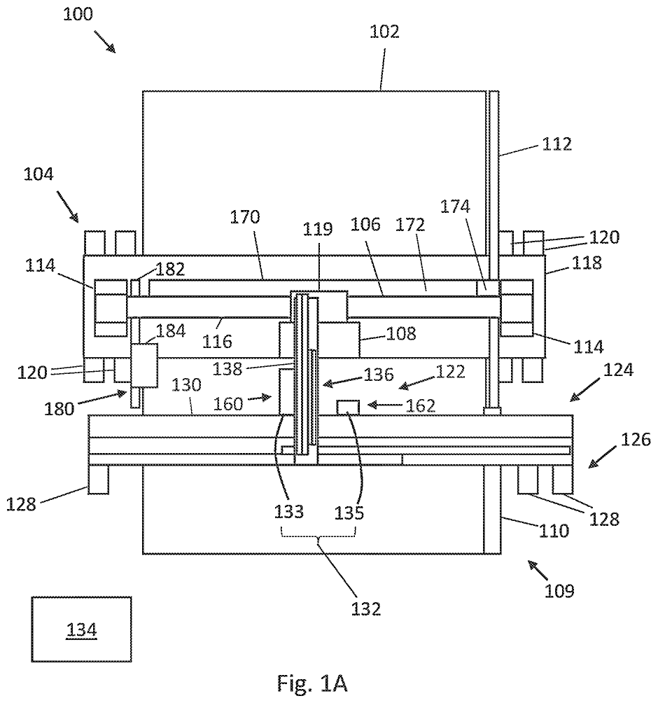

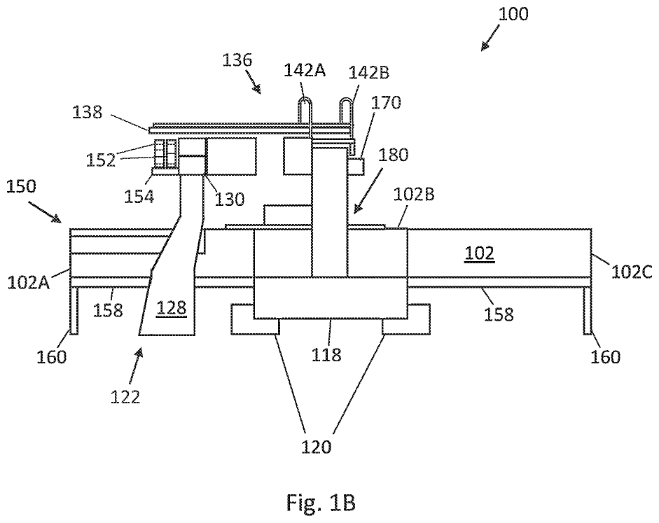

FIG. 1A is a plan view of an inkjet printer 100 according to one embodiment. The inkjet printer 100 has a substrate support 102 that supports a substrate for processing by the inkjet printer 100. A print assembly 104 is disposed across the substrate support 102. The print assembly 104 comprises a print support 106 and a printhead assembly 108 movably coupled to the print support 106. The substrate support 102 supports a substrate to allow the printhead assembly to eject droplets of one or more print materials onto the substrate. The substrate support 102 may be a gas support that floats the substrate on a gas cushion. A substrate holder assembly 109 is disposed beside the substrate support 102 to engage with an edge of a substrate disposed on the substrate support 102. The substrate holder assembly 109 comprises a substrate holder 110 movably disposed on a substrate holder support 112. The substrate holder 110 attaches to a substrate floating on the substrate support 102 and moves along the substrate holder support 112 to move the substrate so that desired areas of the substrate can be positioned for printing. The substrate support 102 generally has a longitudinal axis extending in a first direction, which is the direction in which the substrate is transported by the substrate holder 110 during processing. The substrate holder 110 may be supported on the substrate holder support 112 using a gas cushion so that the substrate holder 110 moves along the substrate holder support 112 in the direction of the longitudinal axis of the substrate support 102 substantially without friction.

The print support 106 has two stands 114, one on each opposite side of the substrate support 102, and a beam 116 that extends along a lateral axis of the substrate support 102 between the two stands 114, from one stand 114 to the other stand 114, substantially perpendicular to the longitudinal axis. The printhead assembly 108 moves along the beam 116 in the direction of the lateral axis, while the substrate is moved in the direction of the longitudinal axis. Using this “split-axis” system, the printhead assembly 108 and substrate can be relatively positioned to deposit print material at any desired location on the substrate.

The substrate support 102 and the two stands 114 are supported on a base 118 made of a massive material to absorb ambient vibration and prevent transmission of such vibration to the substrate or the printhead assembly 108. The base 118, can, in turn, be supported on one or more isolators 120 that provide a gas cushion to support the base 118, further isolating the substrate and printhead assembly 108 from ambient vibrations. The stands 114 and beam 116 can also be made of a massive material to absorb vibration. The printhead assembly 108 is coupled to the beam 116 by a carriage 119, which can be a gas cushion carriage to move the printhead assembly 108 along the beam 116 substantially without friction.

As noted above, reducing exposure of the substrate and the printhead assembly 108 to ambient vibration and/or other unwanted movement is helpful for maximizing print precision of the inkjet printer 100. To further help reduce transmission of unwanted movement to the printhead assembly 108, a supply assembly 122 is spaced apart from the print assembly 106 so that equipment of the supply assembly 122 does not add unwanted movement to the printhead assembly 108. The supply assembly 122 comprises a supply support 124 with a support structure 126 that has an irregular polyhedral shape selected to minimize vibration. The support structure 126 has a plurality of stands 128 that, in this case, rest on a floor, and not on the base 118. Since the supply assembly 122 is spaced apart from the print assembly 106, more vibration can be tolerated at the supply assembly 122, and equipment of the supply assembly 122, such as pumps and compressors, can add vibration. It is still helpful to reduce the incidence of ambient vibration transmitted through the support structure 126, so the polyhedral shape of the stands 128, and the number of stands 128, are selected to minimize ambient vibration transmitted to the supply assembly 122.

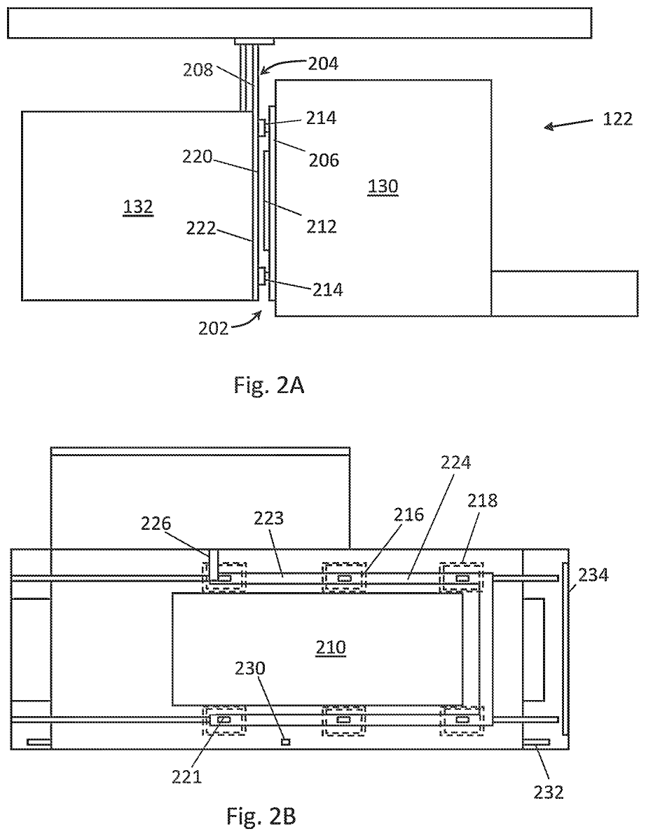

The support structure 126 has a beam 130 that extends substantially parallel to the beam 116 of the print assembly 106. The supply assembly 122 has a supply unit 132 that comprises a fluid unit 133 and an electrical unit 135. The supply unit 132 is movably coupled to the beam 130 to move in a direction substantially parallel to the direction of the printhead assembly 108. The printhead assembly 108 and the supply unit 132 are not rigidly connected and can move, relative to one another, in three dimensions. A controller 134 is configured to monitor position of, and control movement of, the printhead assembly 108 and the supply unit 132 such that distance between the printhead assembly 108 and the supply unit 132 is kept within a predetermined tolerance. Thus, variation of the distance between the printhead assembly 108 and the supply unit 132 is kept below a predetermined tolerance. The controller 134 can also be configured to synchronize movement of the printhead assembly 108 and the supply unit 132 to minimize abrupt forces on the printhead assembly 108. For example, the controller 134 can be supplied with known timing of control loops and components of the movement systems of the printhead assembly 108 (i.e. the carriage 119) and the supply unit 132 (described in detail in connection with FIGS. 2A and 2B below) to time issuing control signals to the movement systems such that accelerations of the printhead assembly 108 and the supply unit 132 are as close to simultaneous as possible.

The supply unit 132 is connected with the printhead assembly 108 by a plurality of conduits 136, which are supported by a bridge 138. The bridge 138 is connected to the supply assembly 122, and may be connected to the supply unit 132. Alternately, the bridge 138 may be connected to the printhead assembly 108. The bridge 138 supports the conduits 136 connecting the supply unit 132 with the printhead assembly 108 so that movement of the conduits 136 with respect to the printhead assembly 108 is minimized. In this way, movement of the conduits 136 does not create unwanted forces on the printhead assembly 108 to diminish precision of printhead positioning.

The supply assembly 122 is positioned in a spaced apart relationship to the print assembly 106, as mentioned above. FIG. 1B is an elevation view of the inkjet printer 100 of FIG. 1A. The printhead assembly 108 is on a side of the beam 116 that faces an input end 150 of the substrate support 102. The substrate holder 110 is movable to the input end 150 of the substrate support 102 to engage with a substrate placed at the input end 150 by a substrate handler (not shown). The supply assembly 122 is positioned on the input side of the substrate support 102 such that the bridge 138 can span from the supply assembly 122 to the printhead assembly 108. As noted above, the stands 128 have an irregular polyhedral shape to suppress transmission of ambient vibration to the supply unit 132. The supply unit 132 is on a side of the beam 130 that faces the printhead assembly 108 to minimize distance between the two units. In general, the supply unit 132 is positioned as close as possible to the printhead assembly 108, as limited by the positions of other structures of the inkjet printer 100, to minimize the complexity of coordinating movement of the two units and flowing fluids between the two units.

The bridge 138 extends beyond the beam 130 toward the input end 150 of the substrate support 102 to provide interaction with one or more service bundles 152 disposed on a service bundle support 154 positioned on a side of the beam 130 facing the input end 150 of the substrate support 102, and facing away from the print assembly 106. The service bundle support 154 is attached to the beam 130 and extends away from the beam 130 toward the input end 150 to provide a support surface for the one or more service bundles 152 that couple the supply unit 132 and the conduits 136 to fluid and electrical systems for operating the inkjet printer 100.

The conduits 136 can be connected with the printhead assembly 108 and/or the carriage 119 using flexible conduits 142. A first flexible conduit 142A, which can be a flexible conduit bundle (i.e. multiple flexible conduits grouped together) is shown fluidly connecting the conduits 136 (specific conduits, as appropriate) to the printhead assembly 108 and a second flexible conduit 142B, which can also be a flexible conduit bundle, is shown fluidly connecting the conduits 136 to the carriage 119. The flexible conduits 142 are omitted from the plan view of FIG. 1A to simply the figure, but such flexible conduits can be used, or not used, in the embodiments of FIGS. 1A and 1B. The flexible conduits 142 can help further insulate the printhead assembly 108 and/or the carriage 119 from unwanted forces generated by movement of the supply unit 132, the conduit support 138, and the conduits 136, to the extent such movement is not perfectly synchronized with movement of the printhead assembly 108.

As noted above, the base 118 can be disposed on floatation isolators, such as the isolators 120. The substrate support 102, here, is in three sections, an input section 102A, a print section 102B, and a staging section 102C. The print section 102B is between the input section 102A and the staging section 102C. The staging section 102C can be an output zone for substrates to be retrieved from the inkjet printer 100, or in some embodiments the staging section 102C can be a substrate rotation stage to change orientation of a substrate. The print section 102B supports a substrate during deposition of print material on the substrate from the printhead assembly 108. The print section 102B is therefore directly supported by the base 118 to minimize disturbance of the floating substrate and the deposition process. Lateral supports 158, for example steel beams, extend from the base 118 in the longitudinal direction of the substrate support 102 to support the input section 102A and the staging section 102C. End posts 160 are disposed at the ends of the lateral supports 158 to supplement support for the substrate support 102. The end posts 160 can rest on the floor while the base 118 rests on a thin gas cushion created by the isolators 120. Ambient vibration that might be transmitted from the end posts 160 through the lateral supports 158, the input section 102A, and the staging section 102C to the base 118 and the print section 102B are substantially attenuated by the gas cushion support for the base 118 on the isolators 120 and by the gas cushion support for the substrate provided by the print section 102B. It should be noted that gas cushion capability may also be coupled to the input section 102A and the staging section 102C to provide continuous gas cushion support for a substrate at all locations of the substrate support 102.

The supply assembly 122 is configured such that elevation change between the supply unit 132 and the printhead assembly 108 is minimized or otherwise kept low to reduce head pressure of dense fluids being transferred between the supply unit 132 and the printhead assembly 108. Keeping head pressure of such fluids low reduces the pumping capacity needed to transfer such fluids. In general, it is helpful to establish a difference in elevation between the supply assembly and the print assembly that is compatible with pumping capacity of the supply assembly. Because print materials to be transferred from the supply assembly to the print assembly, and optionally back to the supply assembly in a loop, can be dense and viscous, and can require relatively large pumping force to transfer, it is helpful to minimize, or not overly amplify, head pressure in the print material circuit between the supply assembly and the print assembly. Thus, the print assembly, or the printhead assembly, is at a first elevation and the supply assembly is at a second elevation. The second elevation may be the same as the first elevation, or the second elevation may be different from the first elevation by an amount selected to be compatible with pumping capacity of the supply assembly. In this way, pumping capacity of the supply assembly to transfer print material to the printhead assembly, and optionally back to the supply assembly in a loop, is not exceeded, and size and energy use of pumps disposed in the supply assembly can be minimized or effectively selected. Although a large elevation difference can be operable, larger pumping capacity and energy consumption is needed to transfer fluids at large elevation differences. Large elevation differences can also lead to larger vertical dimension of the inkjet printer 100, thus requiring more space to operate the printer. The elevation difference can be measured using any convenient features or markers of the supply assembly and the print assembly. For example, the elevation difference may be based on a top or a bottom of a print material reservoir of the supply assembly and of the print assembly. Alternately, the elevation different may be based on an elevation of one or more pumps of the supply assembly and a top or bottom of a print reservoir of the print assembly fluidly coupled to the one or more pumps of the supply assembly. Any other convenient elevations of the supply assembly and the print assembly can be used.

FIG. 2A is a side view of a portion of the supply assembly 122. The supply unit 132 is coupled to a linear motion system 202 that is attached to the beam 130 on a side of the beam 130 facing the printhead assembly 108 (not shown in FIG. 2A). The supply unit 132 is therefore attached to the side of the beam 130 facing the printhead assembly 108. A carriage unit 204 couples the supply unit 132 to a track 206 that is attached to the side of the beam 130. The carriage unit 204 comprises a bearing plate 208 that couples to the track 206 and an actuator 210 (see FIG. 2B) that couples to the bearing plate 208 and/or the track 206. FIG. 2B is a plan view of the bearing plate 208. In this case, the actuator 210 is an inductive actuator, so the actuator 210 couples inductively to a magnet structure 212 (see FIG. 2A) that is mechanically coupled to the track 206. The track 206 has two rails 214 that extend along the length of the track 206, and the magnet structure 212 is disposed between the two rails 214 and attached to the track 206.

The bearing plate 208 has at least two bearing blocks 216 that couple to the rails 214, at least one bearing block 216 for each rail 214. In this case, there are three bearing blocks 216 coupled to each rail 214 for a total of six bearing blocks 216. Any suitable number of bearing blocks 216 can be used. Each bearing block 216 is disposed within a housing 218 that controls particles generated by movement of the bearing block 216 against the rail 214. The bearing plate 208 has a first side 220 that faces the track 206 when the bearing plate 208 is mounted to the track 206, and a second side 222, opposite from the first side 220, to which the supply unit 132 is mounted. The bearing blocks 216 and housings 218 are disposed on the first side 220 of the bearing plate 208, the second side 222 of which is shown in FIG. 2B. The bearing blocks 216 and housings 218 are therefore shown in phantom in FIG. 2B. The bearing plate 208 has an opening 221 from the first side 220 to the second side 222 thereof at the location of each housing 218 to provide an exhaust pathway for particles generated within each housing 218 by movement of the bearing plate. The openings 221 are formed in a groove 223 formed in the surface of the second side 222. A cover (not shown) is placed over the groove to form an exhaust plenum 224. An exhaust conduit 226 is attached to the exhaust plenum 224 on the second side 222 of the bearing plate 208. Particles generated by movement of the bearing blocks 216 on the rails 214 are captured in the housings 218. The particles are exhausted through the openings 221, thus through the bearing plate 208, to the exhaust plenum 224 and are removed by the exhaust conduit 226. An exhaust handler (not shown) is fluidly coupled to the exhaust conduit 226 to flow the particles out of the carriage unit 204. The exhaust handler may be located on the supply assembly 122 or in a service unit adjacent to the inkjet printer 100. Particle generation by movement of the bearing blocks 216 along the rails 214 is thus captured by the housings 218 and exhausted through the bearing plate 208 to the exhaust conduit 226.

The exhaust plenum 224 extends around a periphery of the bearing plate 208. The actuator 210 is generally located at a central location of the bearing plate 208 so the actuator 210 can couple with the track 206 in a convenient manner. The actuator 210 may be disposed in a recess, or opening, formed in the bearing plate 208 so that the second side 222 of the bearing plate 208 is flat to accommodate attachment of the supply unit 132 on the second side 222 of the bearing plate 208. In this case, the actuator 210 is located to provide magnetic coupling with the magnet structure 212 attached between the rails 214 of the track 206. The exhaust plenum 224, in this case, extends around three sides of the rectangular inductive actuator 210.

The linear motion system 202 can have one or more position sensors 230 to sense position of the carriage unit 204. In this case, the position sensor 230 is attached to the bearing plate 208. Here, the position sensor 230 is an encoder, and an encoder strip 232 is disposed on the track 206 to couple with the encoder 230 and signal position as the carriage unit 204 moves along the track 206. Other positions sensors, such as optical position sensors, can be used in addition to, or instead of, encoders. The linear motion system 202 can also have one or more restraints 234 to limit motion of the carriage unit 204 along the track 206. Here, an end stop restraint is used at an end of the track 206.

Referring again to FIG. 1A, the fluid unit 133 is generally located at a first end 160 of the supply unit 132, and the electrical unit 135 is generally located at a second end 162, laterally displaced from the first end 160 along the beam 130. The supply unit 132 is generally configured such that the fluid unit 133 is located adjacent to a fluid unit (not shown) of the printhead assembly 108 while the electrical unit 135 is located adjacent to an electrical unit (not shown) of the printhead assembly 108, where the fluid unit of the printhead assembly 108 is located at a first end of the printhead assembly 108 and the electrical unit of the printhead assembly 108 is located as a second end of the printhead assembly 108, opposite from the first end of the printhead assembly 108. The fluid and electrical units of the printhead assembly 108 and the supply unit 132 are adjacent to simplify maintenance of the various units. For example, to maintain the two fluid units, the printhead assembly 108 and the supply unit 132 can be moved to an end of their respective beams 116 and 130 to position the fluid units at a side of the inkjet printer 100 for access by maintenance personnel. Likewise, to maintain the electrical units, the printhead assembly 108 and the supply unit 132 can be moved to an opposite end of their respective beams 116 and 130 to position the electrical units at an opposite side of the inkjet printer 100 for access.

The print assembly 106 may include a ventilation unit 170 coupled to the print support 106 to exhaust the printhead assembly. The ventilation unit 170 comprises a plenum 172 attached to the print support 106 and fluid connected to an interior of the printhead assembly 108. The ventilation unit 170 also comprises an exhaust handler 174 fluidly coupled to the plenum 172 to flow gas through the plenum 172 and the printhead assembly 108 to remove particles generated by movement of the printhead assembly 108 and operation of equipment within the printhead assembly 108. In the inkjet printer 100, the supply unit 132 and the printhead assembly 108 are separately ventilated.

The inkjet printer 100 can include a maintenance station 180. The maintenance station 180 is positioned beside the substrate support 102 at a location accessible to the printhead assembly 108 by moving the printhead assembly 108 along the print support 106 to the side of the substrate support 102. The maintenance station 180 is, in this case, located at the side of the substrate support 102 opposite from the substrate holder assembly 109 to avoid interfering with operation of the substrate holder assembly 109. The maintenance station 180 can include a motion system 182 for positioning the maintenance station 180 for optimal access by the printhead assembly 108 along with one or more instruments 184 for performing maintenance and/or calibration operations with the printhead assembly 108. Such operations may include diagnostic operations and cleaning operations.

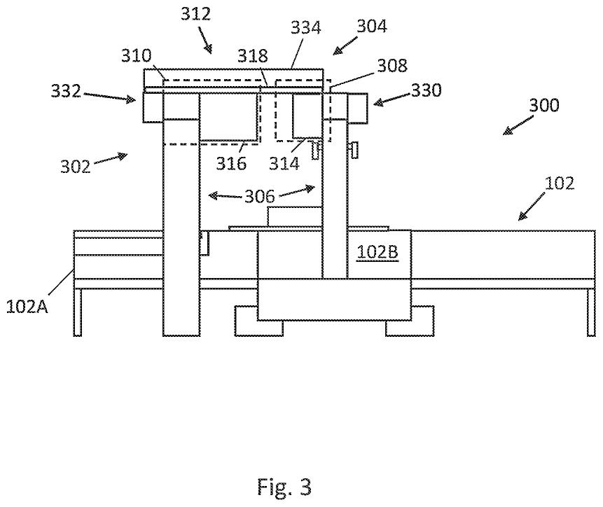

FIG. 3 is a plan view of an inkjet printer 300, according to another embodiment. The inkjet printer 100 of FIG. 1A is an example of the inkjet printer 300, and elements identical between the two printers are given the same reference numeral in FIG. 3 as in FIG. 1A. The inkjet printer 300 has a processing assembly 302 arranged across the substrate support 102. The processing assembly 302 comprises a processing unit 304 supported by a support structure 306 at opposite sides of the substrate support 102, generally adjacent to the print section 102B, and depending on the dimensions of the support structure 306, the input section 102A.

The processing assembly 304 has a deposition section 308 and a supply section 310 that is spaced apart from the deposition section 308 to keep vibration associated with the supply section 310 remote from the deposition section 308. The support structures 306 may be disposed on the base 118, or may be disposed on separate gas cushion isolators, or on footings that are supported by gas cushion isolators, adjacent to the base 118. In this case, the support structure 306 is shown with one component disposed on the base 118 and another component disposed on the floor. Components of the support structure 306 closer to the printhead assembly 108 or the deposition section 308, or most directly supporting either, can be more insulated from ambient vibrations and forces by resting the component on the base or providing separate gas cushion or other insulative support. In some cases, it may be useful to insulate the entire processing assembly 304 from ambient vibration by resting the entire support structure on either the base or partially or completely on a separate insulative support, such as a gas cushion support.

The processing assembly 304 has a processing head 312 that comprises a printhead assembly 314 and a supply unit 316 joined by a conduit support 318. The processing head 312 is movably supported on the components of the support structure 306 by independent movement systems, a first movement system 320A for the deposition section 308 and a second movement system 320B for the supply section 310. A controller 322 is operatively connected with the first and second movement systems 320A and 320B to coordinate movement of the first and second movement systems 320A and 320B. The controller is configured to monitor position of the printhead assembly 314 and the supply unit 316, and to maintain the positions of the printhead assembly 314 and the supply unit 316 such that a distance between the printhead assembly 314 and the supply unit 316 is within a predetermined tolerance. The controller 322 may also be configured to maintain a velocity of the printhead assembly 314 and a velocity of the supply unit 316 such that a difference between the velocity of the printhead assembly 314 and the velocity of the supply unit 316 is within a predetermined tolerance.

The conduit support 318 spans the support structure 306, from the supply section 310 to the deposition section 308, and provides support for various conduits that connect the supply unit 316 with the printhead assembly 314. These conduits may be connected to the supply unit 316 and the printhead assembly 314 using suitable connections, for example connections that provide mitigation of vibration and movement transmission to the printhead assembly 314 from the supply unit 316 or the conduit support 318.

The processing head 312 may be configured with any amount of mechanical rigidity. Depending on the momentum characteristics of the various units of the processing head 312, more or less rigidity can be provided in the processing head 312 to optimize the effect of movement and vibration on the printhead assembly 314. The supply unit 316 includes one or more pumps and one or more compressors to supply fluids and gases to the printhead assembly 314. The pumps and compressors generate vibration that the processing head 312, for example the conduit support 318, can be configured to dampen. One way to dampen vibration transmission from the supply unit 316 or the supply section 310 to the printhead assembly 314 or the deposition section 308 is the use the flexible connections described above in connection with FIG. 1B.

In some cases, the printhead assembly 314 is disposed adjacent to one component of the support structure 306, may be movably supported on a rail disposed on one component of the support structure 306 by movable support of any suitable type, for example by a gas cushion support, and may be moved along the rail by a linear actuator, which can be a physical actuator or an inductive actuator. The supply unit 316 can likewise be disposed adjacent to a component of the support structure 306, and is separately actuated to avoid moments and vibrations that would arise from actuating only one end of the processing head 312. Alternately, a dual actuator can be used that simultaneously moves the entire processing head 312 along both rails. In another alternative, a third rail may be disposed between the two rails 320 to serve as a drive rail, for example to use with a screw drive, linear inductive drive, or other precision linear positioning drive, while the ends of the processing head 312, at the printhead assembly 314 and the supply unit 316, are passively supported on the rails by sliding supports such as gas cushion supports. Where the components of processing head 312, the printhead assembly 314 or deposition section 308 and the supply unit 316 or supply section 310, are separately actuated, position sensors can be provided on the printhead assembly 314 and the supply unit 316, and a controller can be configured to monitor position of the printhead assembly 314 and the supply unit 316 and dynamically adjust the positions of the printhead assembly 314 and the supply unit 316 to maintain a distance between the position sensors, in the travel direction, that is less than a predetermined tolerance. The controller can also be configured to monitor velocity of the printhead assembly 314 and the supply unit 316 and dynamically adjust the velocities of the printhead assembly 314 and the supply unit 316 such that a difference between the velocities of the two is less than a predetermined tolerance.

Using separate actuation of the printhead assembly 314 and the supply unit 316, with precision linear actuators, position sensors, and a controller configured to control the linear actuators as described above, can have advantages in removing inertial and moment effects that can arise where a distributed body is actuated using a point force. Similar results can be obtained by actuating the processing head 312 using a point force placed approximately at the balance point of the processing head 312, by providing a drive rail, as described above. Providing a rigid structure for such a processing head 312 can reduce vibrations transmitted to the ends of the processing head 312, where the supply unit 316 and the printhead assembly 314 are attached, and applying the force near the balance point of the processing head 312 minimizes torques on the processing head 312.

The processing head 312 is generally configured to provide an elevation difference between print material in the supply section 310 and print material in the deposition section 308 that is less than a predetermined tolerance. Managing the difference in elevation allows excess pumping capacity to be avoided, since head pressure resulting from elevation change of print material is kept at or below a maximum value. The head pressure may be minimal if there is essentially no elevation difference between the print material in the supply section 310 and the print material in the deposition section 308, other than the differences in level attending to inventory differences in the two sections.

Continuous ventilation of the supply unit 316, the printhead assembly 314, and the conduit support 318, can be provided. A deposition ventilation structure 330 for the deposition section 308 can be disposed on a component of the support structure 306 at a location adjacent to the deposition section 308. The deposition ventilation structure 330 may be entirely fixed to the support structure 306 to provide a pathway for exhaust gases to be routed away from the deposition section 308, or the deposition ventilation structure 330 may be partially or completely movable with the deposition section 308. For example, a first portion of the ventilation structure 330 can enclose the deposition section 308 and move with the deposition section 308 while a second portion of the ventilation structure 330 is fixed to the support structure 306 to carry away exhaust gases. In some cases, the printhead assembly 314 can have an exhaust system for ventilating the space around the printheads and other apparatus of the printhead assembly 314, such as local print material supply and return apparatus and printhead actuators, that exhausts to the deposition ventilation structure 330. A portion of the ventilation structure 330 can also house conduits, conduit bundles, and/or service bundles serving the deposition section 308 to contain any particle generation from operation of those elements. For example, a service bundle can be disposed within the ventilation structure 330, or a portion thereof, where exhaust gases are routed such that the flow of exhaust gases through the ventilation structure removes any particles generated by the service bundle.

A supply ventilation structure 332 can also be provided for the supply section 310, which can be similar to the ventilation structure 330, and can house conduits, conduit bundles, and/or service bundles serving the supply section 310.

The processing head 312 can also have a processing head ventilation structure 334, which can include an enclosure of the processing head 312. Any particles generated by movement of conduits in the conduit support 318 can be captured and ventilated by continuous gas flow through the conduit support 318. Where one or more of the ventilation structures 330 and 332 are used, the processing head ventilation structure 334 can be exhausted through one of the ventilation structures 330 and 332. Alternately, the processing head ventilation structure 334 can be exhausted through a pathway separate from any other ventilation structure.

The support structure 306 can also be used to support an imaging component 340. Here, two imaging components 340 are shown. The imaging component 340 can be any combination of light sources, motion or positioning systems, optical systems such as focusing and filtering mechanisms, and image capture components such as cameras or photodiode arrays. The imaging component 340 can be an inspection device or a calibration device, or both, that can be used to determine and compensate for and or all of substrate or feature positioning, substrate holder positioning or performance, and processing head positioning or performance. The imaging component 340 can also be used to monitor the result of maintenance activities performed by the maintenance station 180. The imaging component 340, or all the imaging components 340, can be mounted to an available location of the support structure 306, such as the bottom of a rail supporting the printhead assembly 314, and can be provided with a movement system to move the imaging component 340 along the support structure 306 to needed locations. Where more than one imaging component 340 is provided, separate mounts and movement systems can be provided to allow independent positioning of the imaging components 340, as space allows.

While the foregoing is directed to embodiments of one or more inventions, other embodiments of such inventions not specifically described in the present disclosure may be devised without departing from the basic scope thereof, which is determined by the claims that follow.

1. An inkjet printer, comprising:
a substrate support;
a print assembly disposed at a first elevation across the substrate support; and
a supply assembly spaced apart from the print assembly, connected to the print assembly, and disposed at a second elevation that is the same as the first elevation, or that is different from the first elevation by an amount selected to be compatible with pumping capacity of the supply assembly.

2. The inkjet printer of claim 1, wherein the supply assembly is disposed across the substrate support.

3. The inkjet printer of claim 1, wherein the supply assembly comprises a support structure with an irregular polyhedral shape selected to minimize vibration.

4. The inkjet printer of claim 1, wherein the supply assembly is connected to the print assembly by a plurality of conduits supported by a bridge.

5. The inkjet printer of claim 4, wherein the print assembly comprises a printhead assembly movably coupled to a printhead support and the supply assembly comprises a supply unit movably coupled to a supply support, wherein the printhead assembly and the supply unit are not rigidly connected and are movable in parallel directions, and the printer further comprises a controller configured to control movement of the printhead assembly and the supply unit such that variation of a distance between the printhead assembly and the supply unit is less than a predetermined tolerance.

6. The inkjet printer of claim 4, wherein the plurality of conduits comprises a print material supply conduit and a print material return conduit.

7. The inkjet printer of claim 4, wherein the supply assembly includes an exhaust handler coupled to the supply unit.

8. The inkjet printer of claim 5, wherein the bridge is connected to the supply unit to move with the supply unit.

9. The inkjet printer of claim 4, wherein the plurality of conduits includes a power supply conduit, a gas supply conduit, a print material supply conduit, and a print material return conduit.

10. The inkjet printer of claim 6, wherein the print material supply and return conduits fluid connect a print material supply system of the supply unit with a print material supply system of the printhead assembly.

11. A inkjet printer, comprising:
a substrate support having an input section and a print section; and
a processing assembly comprising a support structure, a deposition section located in proximity to the print section of the substrate support, and a supply section spaced apart from the deposition section in a direction toward the input section of the substrate support, the processing assembly further comprising a processing head that extends from the deposition section to the supply section, the processing head having a printhead assembly located in the deposition section, a supply unit located in the supply section, and a conduit support connecting the printhead assembly with the supply assembly.

12. The inkjet printer of claim 11, further comprising one or more of a deposition section ventilation structure, a supply section ventilation structure, and a processing head ventilation structure.

13. The inkjet printer of claim 11, wherein the processing head has a rigidity selected to minimize transmission of vibration to the printhead assembly.

14. The inkjet printer of claim 11, wherein the processing head comprises a first movement system for the deposition section, a second movement system for the supply section, and a controller operatively coupled to the first and second movement systems to coordinate movement of the first and second movement systems.

15. The inkjet printer of claim 14, wherein the controller is configured to maintain positions of the printhead assembly and the supply unit such that a distance between the printhead assembly and the supply unit is within a predetermined tolerance.

16. The inkjet printer of claim 11, further comprising an imaging component mounted on the support structure.

17. The inkjet printer of claim 13, wherein the processing head comprises flexible connections to insulate the printhead assembly from vibration.

18. An inkjet printer, comprising:
a substrate support;
a print assembly disposed across the substrate support;
a supply assembly spaced apart from the print assembly and configured with the print assembly to minimize a difference in elevation between the supply assembly and the print assembly; and
a conduit support between the print assembly and the supply assembly.

19. The inkjet printer of claim 18, further comprising a plurality of conduits disposed on the conduit support and connected to the print assembly using flexible connections that attenuate transmission of forces from the supply assembly to the print assembly.

20. The inkjet printer of claim 18, wherein the plurality of conduits comprises a print material supply conduit and a print material return conduit.
